(19) United States
(12) Patent Application Publication
(10) Pub. No.: US 2010/0207164 A1
(43) Pub. Date: Aug. 19, 2010

(54) FIELD EFFECT TRANSISTOR

(76) Inventors: Daisuke Shibata, Osaka (JP); Tatsuo Morita, Kyoto (JP); Yasuhiro Uemoto, Shiga (JP)

Correspondence Address: MCDERMOTT WILL & EMERY LLP, 600 13TH STREET, NW, WASHINGTON, DC, 20005-3096, US

(21) Appl. No.: 12/682,007

(22) PCT Filed: Aug. 7, 2009
(86) PCT No.: PCT/JP2009/003805

§ 371 Date: Apr. 7, 2010

(30) Foreign Application Priority Data
Aug. 22, 2008 (JP) 2008-214382

(51) Int. Cl. H01L 29/772

(52) U.S. Cl. 257/192; 257/E29.242

(57) ABSTRACT

A field effect transistor includes a first nitride semiconductor layer 13 and a second nitride semiconductor layer 14 having a band gap larger than that of the first nitride semiconductor layer 13 which are formed in this order in an upward direction on a conductive substrate 11, a source electrode 15 and a drain electrode 16 which are electrically connected to a two-dimensional electron gas layer 21, and a gate electrode 18. A rise voltage of a drain-substrate current is lower than a rise voltage of a drain-gate current and a rise voltage of a drain-source current.

### TECHNICAL FIELD

The present disclosure relates to a field effect transistor, and particularly to a heterojunction field effect transistor using a nitride semiconductor.

### BACKGROUND ART

Gallium nitride (GaN) and aluminum nitride (AlN) have respective band gaps as large as 3.4 eV and 6.2 eV at room temperature. Therefore, a nitride semiconductor represented by GaN is a wide-gap semiconductor having a high breakdown field and a higher saturated electron drift velocity than those of a compound semiconductor such as gallium arsenide (GaAs), a silicon (Si) semiconductor, and the like.

In a hetero structure of aluminum gallium nitride (AlGaN) and GaN, charges are generated at a heterointerface due to spontaneous polarization and piezoelectric polarization on the (0001) plane. As a result, a two-dimensional electron gas (2DEG) layer having a sheet carrier density of 1×10¹³ cm⁻² or higher is obtained even when the hetero structure is undoped. By using the 2DEG layer generated at the heterointerface, a heterojunction field effect transistor (HFET) having a high current density can be implemented.

The nitride semiconductor having characteristic features as described above is appropriate for a power transistor of which a high output and a high breakdown voltage are required, and therefore has been actively investigated and developed. For example, in the fields that require a high breakdown voltage of 200 V or more, an on-resistance as low as one tenth or less of that of a metal-oxide-film semiconductor field effect transistor (MOSFET) using Si and one third or less of that of an insulated gate bipolar transistor (IGBT) has been implemented (see, e.g., NON-PATENT DOCUMENT 1).

Note that AlGaN is a ternary compound of a formula AlₓGa₁₋ₓN (where 0≦x≦1). Hereinafter, a multi-element compound is simply represented by an arrangement of the respective symbols of the individual constituent elements such as, e.g., AlInN or GaInN. For example, AlₓGa_{1-x-y}In_{y}N (where 0≦x≦1, 0≦y≦1) is simply represented as AlGaInN.

### CITATION LIST

### Non-Patent Document

NON-PATENT DOCUMENT 1: W. Saito et al., “IEEE Transactions on Electron Devices,” 2003, Vol. 50, No. 12, p. 2528

### SUMMARY OF THE INVENTION

### Technical Problem

However, when a HFET using a nitride semiconductor is applied to a circuit such as an inverter, such problems as shown below arise which may not arise when a device using Si, such as a MOSFET, is used.

When an inductive load is connected to a circuit such as an inverter, energy accumulated in the inductive load needs to be consumed within the circuit at the time of turn-off during the switching operation. The energy E accumulated in the inductive load is represented by a formula of E=½LI², where L is the self-inductance of the inductive load, and I is a current.

The maximum energy that can be consumed without causing breakdown of a device forming an inverter or the like is represented as an avalanche resistance. A MOSFET using Si has a relatively high avalanche resistance. This is attributed to the fact that the MOSFET has a parasitic diode. The parasitic diode is connected antiparallel between the drain and the source, wherein the cathode is connected to the drain, and the anode is connected to the source.

When a sufficiently high electric field is applied to the p-n junction of the parasitic diode, an electron acquires high kinetic energy to be accelerated. The accelerated electron impinges on an atom forming a crystal lattice to generate an electron-hole pair. The electron-hole pair generated acquires energy from the electric field to generate another electron-hole pair. The foregoing process is repeated to result in an avalanche breakdown phenomenon in which the number of carriers rapidly increases. In an avalanche region where the avalanche breakdown phenomenon occurs, a large current called an avalanche current flows. Therefore, the MOSFET can consume the energy from the inductive load using the avalanche region of the parasitic diode.

On the other hand, the conventional HFET does not have a parasitic diode. Accordingly, the energy from the inductive load should be consumed in the 2DEG layer as a channel. However, since the 2DEG layer has a sheet-like shape, a current flows in an extremely narrow range to cause local heat generation. Because the local heat generation destroys a device, the avalanche resistance is low, and it is difficult to turn off the inductive load having a large self-inductance.

The avalanche resistance can be increased by externally connecting a diode between the drain and source of the conventional HFET. In this case, however, the problems of an increased number of components and increased cost arise.

An object of the present disclosure is to solve the problems described above, and allow a HFET having a high avalanche resistance to be implemented without increasing the number of components.

### Solution to the Problem

In order to attain the above object, the present disclosure provides a field effect transistor with a structure in which energy accumulated in an inductive load is three-dimensionally consumed in an entire device.

Specifically, a first field effect transistor according to the present disclosure includes: a conductive substrate; a first nitride semiconductor layer and a second nitride semiconductor layer having a band gap larger than that of the first nitride semiconductor layer which are formed in this order in an upward direction on the conductive substrate; a source electrode and a drain electrode which are electrically connected to a two-dimensional electron gas layer formed in a portion of the first nitride semiconductor layer adjacent to an interface thereof with the second nitride semiconductor layer; and a gate electrode formed between the source electrode and the drain electrode, wherein a rise voltage of a drain-substrate current is lower than a rise voltage of a drain-gate current and a rise voltage of a drain-source current.

In the first field effect transistor, the rise voltage of the drain-substrate current is lower than the rise voltage of the drain-gate current and the rise voltage of the drain-source current. As a result, a current resulting from the counter electromotive force of an inductive load flows not via the two-dimensional electron gas layer, but from the drain electrode to the conductive substrate. Therefore, energy accumulated in the inductive load can be consumed in an entire device, and accordingly a local temperature rise can be inhibited. This allows a heterojunction field effect transistor having a high avalanche resistance to be implemented without increasing the number of components.

The first field effect transistor may further include: a p-type nitride semiconductor layer formed between the conductive substrate and the first nitride semiconductor layer. In this case, the p-type nitride semiconductor layer may be a buffer layer. By providing such a structure, a diode is formed at the interface between the first nitride semiconductor layer and the p-type semiconductor layer. This allows the rise voltage of the drain-substrate current to be controlled with the reverse breakdown voltage of the diode.

The first field effect transistor may further include: a via metal connecting the source electrode and the p-type nitride semiconductor layer.

In the first field effect transistor, the drain electrode may have a structure in which a bottom portion thereof reaches a position under the two-dimensional electron gas layer, but is not in contact with the conductive substrate. By providing such a structure, a drain-substrate breakdown voltage can be reduced to be lower than a drain-source breakdown voltage. In this case, the bottom surface of the drain electrode may also be located under a bottom surface of the source electrode.

A second field effect transistor according to the present disclosure includes: an insulating substrate; a p-type nitride semiconductor layer formed on the insulating substrate; a first nitride semiconductor layer and a second nitride semiconductor layer having a band gap larger than that of the first nitride semiconductor layer which are formed in this order in an upward direction on the p-type nitride semiconductor layer; a source electrode and a drain electrode which are electrically connected to a two-dimensional electron gas layer formed in a portion of the first nitride semiconductor layer adjacent to an interface thereof with the second nitride semiconductor layer; a gate electrode formed between the source electrode and the drain electrode; and a via metal connecting the source electrode and the p-type nitride semiconductor layer, wherein a reverse breakdown voltage of a diode formed at an interface between the first nitride semiconductor layer and the p-type nitride semiconductor layer is lower than a breakdown voltage of a path in which a current flows from the drain electrode to the source electrode via the two-dimensional electron gas layer.

The second field effect transistor includes the via metal connecting the source electrode and the p-type semiconductor layer, and the reverse breakdown voltage of the diode formed at the interface between the first nitride semiconductor layer and the p-type nitride semiconductor layer is lower than the breakdown voltage of the path in which the current flows from the drain electrode to the source electrode via the two-dimensional electron gas layer. As a result, a current resulting from the counter electromotive force of an inductive load flows from the drain electrode to the source electrode not via the two-dimensional electron gas layer, but via the diode, the p-type nitride semiconductor layer, and the via metal. Therefore, energy accumulated in the inductive load is three-dimensionally consumed in an entire device, and accordingly local heat generation can be inhibited. This allows a heterojunction field effect transistor having a high avalanche resistance to be implemented without increasing the number of components.

In the second field effect transistor, the p-type nitride semiconductor layer may be a buffer layer.

In the second field effect transistor, an area of a bottom surface of the drain electrode is preferably larger than an area of a bottom surface of the source electrode.

### Advantages of the Invention

With the field effect transistor according to the present disclosure, a heterojunction field effect transistor having a high avalanche resistance can be implemented without increasing the number of components.

### BRIEF DESCRIPTION OF THE DRAWINGS

FIG. 1 is a cross-sectional view showing a field effect transistor according to a first embodiment.

FIGS. 2A and 2B are graphs each showing the current-voltage characteristic of a field effect transistor, of which FIG. 2A shows the characteristic of a conventional field effect transistor, and FIG. 2B shows the characteristic of the field effect transistor according to the first embodiment.

FIG. 3 is a cross-sectional view showing a variation of the field effect transistor according to the first embodiment.

FIG. 4 is a cross-sectional view showing a field effect transistor according to a second embodiment.

### DESCRIPTION OF EMBODIMENTS

### Embodiment 1

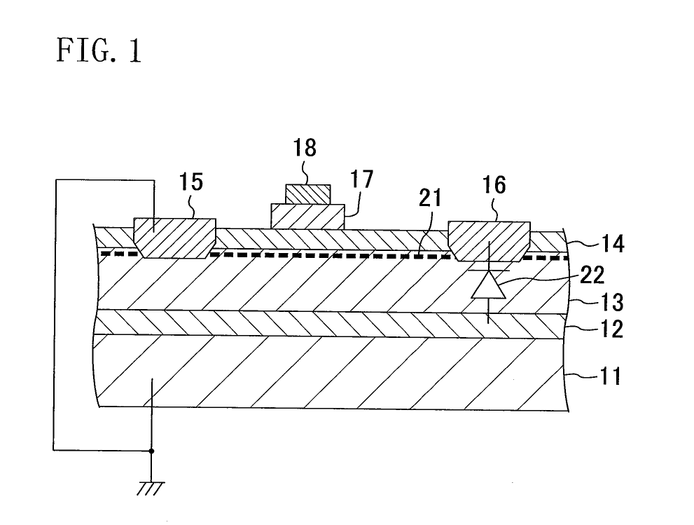

A first embodiment of the present disclosure will be described with reference to the drawings. FIG. 1 shows a cross-sectional structure of a heterojunction field effect transistor (HFET) according to the first embodiment. As shown in FIG. 1, a buffer layer 12 made of p-type AlGaN, a channel layer 13 made of undoped GaN having a thickness of 2 μm, and a barrier layer 14 made of undoped AlGaN having a thickness of 25 nm are formed in this order in an upward direction on a conductive substrate 11. In the portion of the channel layer 13 adjacent to the interface thereof with the barrier layer 14, a two-dimensional electron gas (2DEG) layer 21 serving as a channel is generated.

A gate electrode 18 made of palladium (Pd), nickel (Ni), or the like is formed over the barrier layer 14 via a p-type AlGaN layer 17 having a thickness of 200 nm. A source electrode 15 and a drain electrode 16 each of which is a laminate electrode of titanium (Ti) and aluminum (Al) are formed on both lateral sides of the gate electrode 18. The source electrode 15 and the drain electrode 16 are buried in recessed portions formed by selectively removing the barrier layer 14 and the channel layer 13 so as to reach positions deeper than the 2DEG layer 21.

In the HFET of the present embodiment, the buffer layer 12 is doped to have a p-type conductivity. As a result, a p-n structure is formed between the buffer layer 12 and the 2DEG layer 21 to form a diode 22. Therefore, when the drain electrode 16 and the conductive substrate 11 are connected via the diode 22 and the conductive substrate 11 and the source electrode 15 are grounded, the diode 22 is connected antiparallel between the drain electrode 16 and the source electrode 15. If the reverse breakdown voltage of the diode 22 is reduced to be lower than a drain-source breakdown voltage, it is possible to allow a leakage current, such as an avalanche current when an inductive load is switched, to flow from the drain electrode 16 to the conductive substrate 11.

In the present embodiment, the diode 22 is formed between the p-type buffer layer 12 and the 2DEG layer 21. However, it is also possible to provide a structure in which another p-type semiconductor layer is formed between the buffer layer 12 and the 2DEG layer 21. The source electrode 15 and the conductive substrate 11 are connected and grounded with external wiring, but the source electrode 15 and the conductive substrate 11 may also be connected and grounded by forming a via metal connecting the source electrode 15 and the buffer layer 12 or the conductive substrate 11.

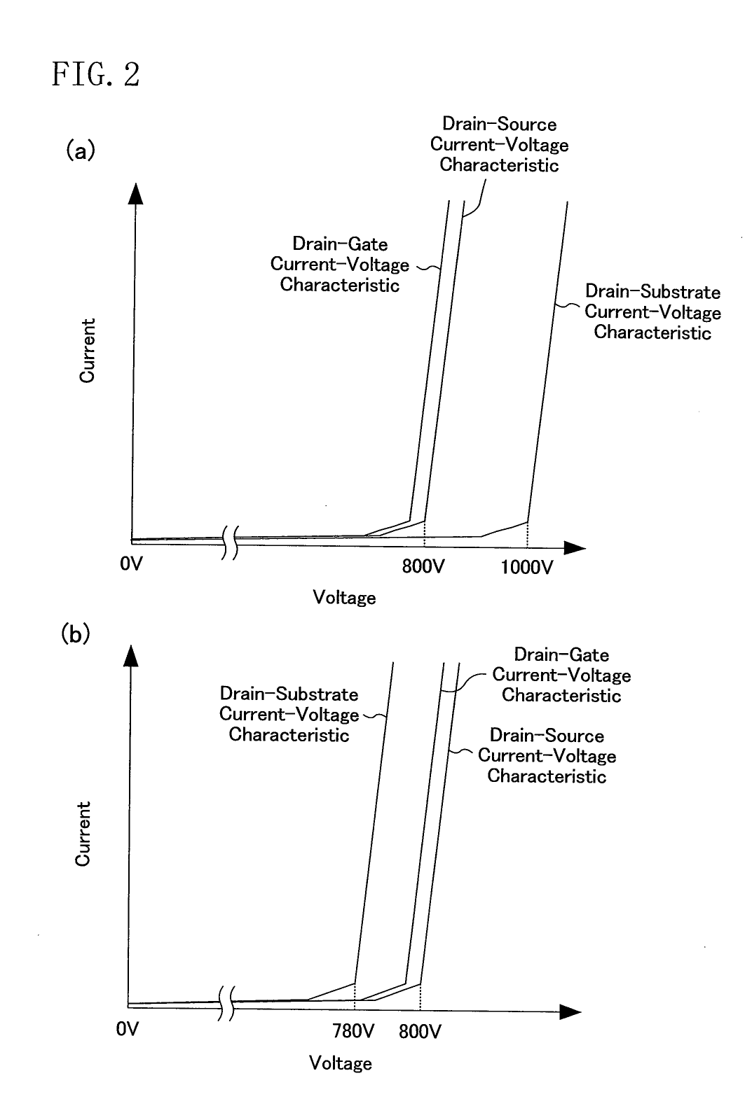

In a conventional HFET, a drain-substrate breakdown voltage is set higher than the drain-source breakdown voltage. For example, in the case of a HFET having a rated breakdown voltage of about 600 V, the drain-source breakdown voltage is set to about 800 V, and the drain-substrate breakdown voltage is set to about 1000 V. In this case, as shown in FIG. 2A, a drain-source current rises in the vicinity of 800 V, and a drain-substrate current rises in the vicinity of 1000 V. As a result, a majority of a current resulting from the counter electromotive force of the inductive load flows in the channel between the drain and the source, and energy accumulated in the inductive load should be consumed two-dimensionally. Consequently, local heat generation occurs to reduce the avalanche resistance of the HFET.

By contrast, in the semiconductor device of the present embodiment, the diode 22 having the reverse breakdown voltage lower than the drain-source breakdown voltage is connected between the drain electrode 16 and the conductive substrate 11. Accordingly, as shown in, e.g., FIG. 2B, the drain-substrate current rises in the vicinity of 780 V, and the drain-source current rises in the vicinity of 800 V. As a result, a majority of the current based on the counter electromotive force of the inductive load flows between the drain and the substrate. In this case, the cross-sectional area of a current path is significantly larger than that of the 2DEG layer 21 serving as the channel, and the energy accumulated in the inductive load can be consumed three dimensionally. Therefore, it is possible to inhibit a local temperature rise due to current concentration, and obtain a high avalanche resistance.

When the rise voltage of the drain-substrate current is lower than the rise voltage of the drain-source current, it is possible to allow the current resulting from the counter electromotive force of the inductive load to flow between the drain and the substrate, not in the channel between the drain and the source, and increase the avalanche resistance. However, since the breakdown voltage of the field effect transistor is determined by the rise voltage of the drain-substrate current, the rise voltage of the drain-substrate current, i.e., the reverse breakdown voltage of the diode 22 is adjusted to be at least 100 V or more, and preferably 300 V or more.

In a voltage range of not less than the rise voltage of the drain-substrate current, it is necessary for the gradient of the drain-substrate current to be equal to or larger than the gradient of the drain-source current. This is because, when the gradient of the drain-substrate current is smaller than the gradient of the drain-source current, if a voltage at the intersection of a drain-substrate current-voltage curve and a drain-source current-voltage curve is exceeded, a current undesirably flows between the drain and the substrate.

The reverse breakdown voltage of the diode 22 is primarily determined by the crystallinity of each of the layers, the impurity concentration of the p-type buffer layer 12, and the film thickness of the channel layer 13. On the other hand, the drain-source breakdown voltage is primarily determined by the crystallinity of each of the layers, and the distance between the source electrode 15 and the drain electrode 16. Therefore, by combining these parameters, the required characteristic of the HFET can be implemented. In the present embodiment, the p-type layer of the diode 22 is the buffer layer 12. This allows easy control of the impurity concentration of the p-type layer, and offers an advantage that the reverse breakdown voltage of the diode 22 can be easily changed.

When the chips of the HFETs are cut from a wafer, an end surface of each of the chips is preferably not provided with a p-i (p-n) junction. When the wafer is cut into the chips, if a p-i junction is exposed at a cut surface, the p-i junction may be destroyed, and a leakage current may increase.

The source electrode 15 and the drain electrode 16 are formed to come in direction contact with the 2DEG layer 21 for a reduction in contact resistance. However, the source electrode 15 and the drain electrode 16 may have any configuration as long as the source electrode 15 and the drain electrode 16 can be brought into ohmic contact with the 2DEG layer 21. In FIG. 1, an example is shown in which the source electrode 15 and the drain electrode 16 are formed to have respective bottom surfaces at the same depth. However, the depth of the source electrode 15 and the depth of the drain electrode 16 may be different from each other. When the depth of the drain electrode 16 is increased, and the distance between the bottom surface of the drain electrode 16 and the buffer layer 12 is reduced, the reverse breakdown voltage of the diode 22 decreases.

Note that, when the area of the bottom surface of the drain electrode 16 is adjusted to be larger than the area of the bottom surface of the source electrode 15, the cross-sectional area of the current path can be increased. That is, a volume in which avalanche energy is consumed can be increased, and therefore a higher avalanche resistance can be obtained.

In FIG. 1, the source electrode 15 is grounded with the external wiring. However, the source electrode 15 may also be grounded by connecting the source electrode 15 and the buffer layer 12 using a source via. Normally, the source via should be connected to the conductive substrate 11. When the substrate is insulating, the source via extending through the substrate should be formed and connected to a back-side electrode formed on the back surface of the substrate or the like. However, in the field effect transistor of the present embodiment, the source electrode 15 can be grounded if the source via is connected to the p-type buffer layer 12. This can reduce the depth of etching when the source via is formed, and also offers an advantage that a process time can be reduced, and cost can be reduced.

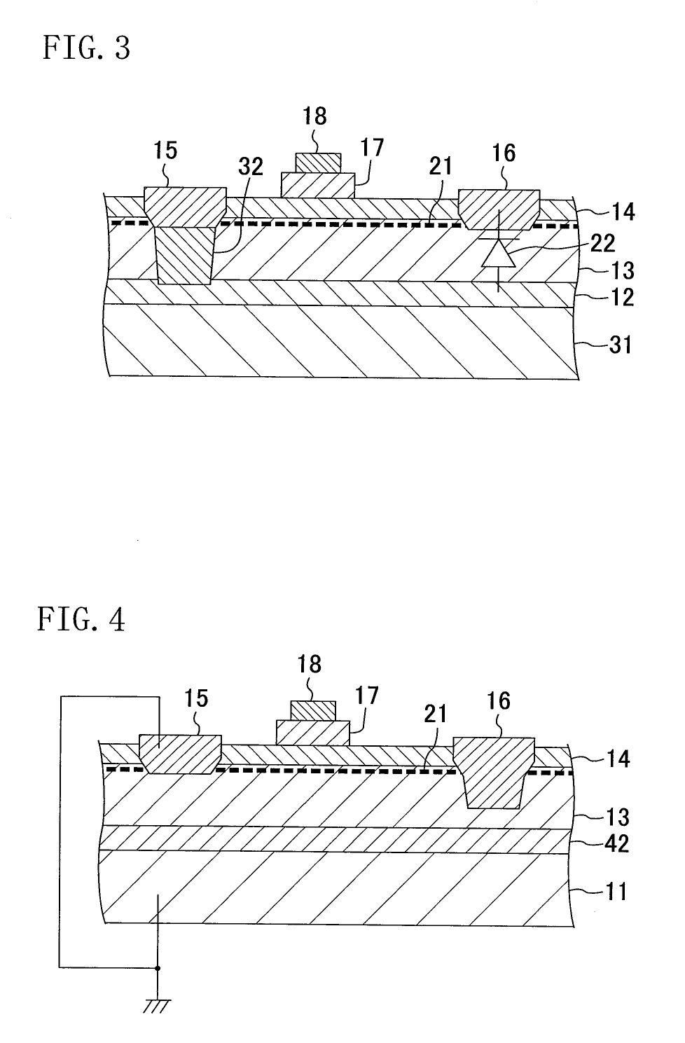

The conductive substrate 11 may be made appropriately of, e.g., silicon (Si) or silicon carbide (SiC). The conductive substrate 11 may also be of an n-type or a p-type. Furthermore, as shown in FIG. 3, an insulating substrate 31 made of high-resistance Si, SiC, sapphire, or the like may also be used instead of the conductive substrate 11. In this case, the source electrode 15 and the buffer layer 12 may be connected appropriately with a source via (via metal) 32.

The reverse breakdown voltage of the diode 22 is lower than the reverse breakdown voltage between the drain electrode 16 and the source electrode 15 in the absence of the diode 22, i.e., the breakdown voltage of a path in which a current flows from the drain electrode 16 to the source electrode 15 via the 2DEG layer 21. Accordingly, a current resulting from the counter electromotive force of the inductive load flows from the drain electrode 16 to the source electrode 15 not via the 2DEG layer 21, but via the diode 22, the p-type buffer layer 12, and the via metal 32. In this case also, the cross-sectional area of the current path increases to be significantly larger than that of the 2DEG layer 21. Therefore, it is possible to inhibit local heat generation, and obtain a high avalanche resistance.

### Embodiment 2

A second embodiment of the present disclosure will be described with reference to the drawings. FIG. 4 shows a cross-sectional structure of a HFET according to the second embodiment. A description of the components in FIG. 4 which are the same as those of FIG. 1 will be omitted by providing the same reference characters.

In the semiconductor device of the second embodiment, as shown in FIG. 4, a buffer layer 42, the channel layer 13, and the barrier layer 14 are formed in this order on the conductive substrate 11. The gate electrode 18 is formed over the barrier layer 14 via the p-type AlGaN layer 17. The source electrode 15 and the drain electrode 16 are formed on both lateral sides of the gate electrode 18. The source electrode 15 is buried in a recessed portion formed by selectively removing the barrier layer 14 and the channel layer 13 so as to reach a position deeper than the 2DEG layer 21. The drain electrode 16 is buried in a recessed portion formed so as to reach a position deeper than the source electrode 15.

The position of the bottom surface of the drain electrode 16 is set such that the drain-substrate breakdown voltage is lower than the drain-source breakdown voltage. The drain-substrate breakdown voltage is affected by the crystallinity of each of the semiconductor layers, but basically determined by the distance between the bottom surface of the drain electrode 16 and the conductive substrate 11. The distance between the bottom surface of the drain electrode 16 and the conductive substrate 11 may be calculated appropriately by considering the thickness of a nitride semiconductor film that can be formed, a generally required breakdown voltage, and the like. It can be considered that the distance between the bottom surface of the drain electrode 16 and the conductive substrate 11 is in a range of about 0.5 μm to 3 μm.

To implement an element having a rated voltage of, e.g., 300 V, a breakdown voltage of about 400 V as a net power is required. That is, the drain-substrate breakdown voltage may be set appropriately to 400 V, and the drain-source breakdown voltage may be set appropriately to about 420 V. In this case, the buffer layer 42 is formed of, e.g., undoped AlGaN having a thickness of 1 μm. Consequently, the breakdown voltage in the portion with the buffer layer 42 is about 300 V. In addition, the channel layer 13 is formed of an undoped GaN layer having a thickness of 2 μm, and the depth of the recessed portion in which the drain electrode 16 is formed is set to 1 μm. The breakdown voltage of the undoped GaN layer is typically about 100 V per micrometer, though it depends on crystallinity. Accordingly, by setting the distance from the bottom surface of the drain electrode 16 to the buffer layer 42 to 1 μm, the breakdown voltage in the portion with the channel layer 13 can be set to about 100 V. Therefore, the drain-substrate breakdown voltage can be set to about 400 V. The drain-gate breakdown voltage can be easily adjusted with the distance between the drain electrode 16 and the gate electrode 18.

In the present embodiment, the drain-substrate breakdown voltage is assured using the film thickness of the channel layer 13 made of GaN and the film thickness of the buffer layer 42 made of AlGaN. Since AlGaN has a band gap larger than that of GaN, a film thickness needed to implement the same breakdown voltage is smaller than that of GaN. Therefore, by providing the buffer layer 42 made of AlGaN, the film thickness of a semiconductor layer grown on the substrate can be reduced to a value smaller than that in the case where the drain-substrate breakdown voltage is assured using only the channel layer 13. This also provides an effect that manufacturing cost can be reduced. Note that the buffer layer 42 may be formed appropriately of a material having a largest possible band gap within a range which allows the buffer layer 42 to be formed on the substrate.

When the rise voltage of the drain-substrate current is lower than the rise voltage of the drain-source current, it is possible to allow the current resulting from the counter electromotive force of the inductive load to flow between the drain and the substrate, not in the channel between the drain and the source, and increase the avalanche resistance. However, since the breakdown voltage of the field effect transistor is determined by the rise voltage of the drain-substrate current, the rise voltage of the drain-substrate current is adjusted to be at least 100 V or more, and preferably 300 V or more.

In the voltage range of not less than the rise voltage of the drain-substrate current, it is necessary for the gradient of the drain-substrate current to be equal to or larger than the gradient of the drain-source current. This is because, when the gradient of the drain-substrate current is smaller than the gradient of the drain-source current, if a voltage at the intersection of the drain-substrate current-voltage curve and the drain-source current-voltage curve is exceeded, a current undesirably flows between the drain and the substrate.

By thus adjusting the drain-substrate breakdown voltage to be lower than the drain-source breakdown voltage, it becomes possible to allow the current resulting from the counter electromotive force of the inductive load to flow between the drain electrode 16 and the conductive substrate 11. Note that the drain-substrate breakdown voltage can also be adjusted not by deepening the recessed portion in which the drain current 16 is formed, but by thinning the film thickness of the channel layer 13. In this case, however, the distance between the gate electrode 18 and the conductive substrate 11 is reduced, and accordingly a gate capacitance may increase to cause a reduction in switching speed.

In FIG. 4, the bottom surface of the drain electrode 16 does not reach the buffer layer 42, but the bottom surface of the drain electrode 16 may also reach the buffer layer 42 as long as a required breakdown voltage is obtained. In the present embodiment also, if the area of the bottom surface of the drain electrode 16 is increased to be larger than the area of the bottom surface of the source electrode 15, a volume in which the avalanche energy is consumed can be increased. As a result, a higher avalanche resistance can be obtained.

The material and film thickness of each of the semiconductor layers shown in the first and second embodiments are only exemplary, and may be changed appropriately depending on the required characteristic of the HFET. For example, the film thickness of the channel layer 13 may be changed appropriately within a range of about 1 μm to 3 μm. Alternatively, the channel layer 13 may contain indium or aluminum. The barrier layer 14 may be an n⁻-type layer having a carrier density of 1×10¹⁵ cm⁻³ to 1×10¹⁷ cm⁻³.

The p-type AlGaN layer 17 is provided for the adjustment of a threshold voltage, and may be omitted if it is not needed.

### INDUSTRIAL APPLICABILITY

The field effect transistor according to the present disclosure allows a heterojunction field effect transistor having a high avalanche resistance to be implemented without increasing the number of components, and is particularly useful as, e.g., a heterojunction field effect transistor using a nitride semiconductor which is used for a power device or the like.

### DESCRIPTION OF REFERENCE CHARACTERS

11 Conductive Substrate
12 Buffer Layer
13 Channel Layer
14 Barrier Layer
15 Source Electrode
16 Drain Electrode
17 AlGaN Layer
18 Gate Electrode
21 2DEG Layer
22 Diode
31 Insulating Substrate
32 Via Metal
42 Buffer Layer

1. A field effect transistor, comprising:
a conductive substrate;
a first nitride semiconductor layer and a second nitride semiconductor layer having a band gap larger than that of the first nitride semiconductor layer which are formed in this order in an upward direction on the conductive substrate;
a source electrode and a drain electrode which are electrically connected to a two-dimensional electron gas layer formed in a portion of the first nitride semiconductor layer adjacent to an interface thereof with the second nitride semiconductor layer; and
a gate electrode formed between the source electrode and the drain electrode, wherein
a rise voltage of a drain-substrate current is lower than a rise voltage of a drain-gate current and a rise voltage of a drain-source current.

2. The field effect transistor of claim 1, further comprising:
a p-type nitride semiconductor layer formed between the conductive substrate and the first nitride semiconductor layer.

3. The field effect transistor of claim 2, wherein the p-type nitride semiconductor layer is a buffer layer.

4. The field effect transistor of claim 2, further comprising:
a via metal connecting the source electrode and the p-type nitride semiconductor layer.

5. The field effect transistor of claim 1, wherein the drain electrode has a bottom portion reaching a position under the two-dimensional electron gas layer but not in contact with the conductive substrate.

6. The field effect transistor of claim 5, wherein the bottom surface of the drain electrode is located under a bottom surface of the source electrode.

7. The field effect transistor of claim 1, wherein an area of a bottom surface of the drain electrode is larger than an area of a bottom surface of the source electrode.

8. A field effect transistor, comprising:
an insulating substrate;
a p-type nitride semiconductor layer formed on the insulating substrate;
a first nitride semiconductor layer and a second nitride semiconductor layer having a band gap larger than that of the first nitride semiconductor layer which are formed in this order in an upward direction on the p-type nitride semiconductor layer;
a source electrode and a drain electrode which are electrically connected to a two-dimensional electron gas layer formed in a portion of the first nitride semiconductor layer adjacent to an interface thereof with the second nitride semiconductor layer;
a gate electrode formed between the source electrode and the drain electrode; and
a via metal connecting the source electrode and the p-type nitride semiconductor layer, wherein
a reverse breakdown voltage of a diode formed at an interface between the first nitride semiconductor layer and the p-type nitride semiconductor layer is lower than a breakdown voltage of a path in which a current flows from the drain electrode to the source electrode via the two-dimensional electron gas layer.

9. The field effect transistor of claim 8, wherein the p-type nitride semiconductor layer is a buffer layer.

10. The field effect transistor of claim 8, wherein an area of a bottom surface of the drain electrode is larger than an area of a bottom surface of the source electrode.
